(19) United States
(12) Patent Application Publication
(10) Pub. No.: US 2014/0318455 A1
(43) Pub. Date: Oct. 30, 2014

(54) LOW EMISSIVITY ELECTROSTATIC CHUCK

(71) Applicant: VARIAN SEMICONDUCTOR EQUIPMENT ASSOCIATES, INC., Gloucester, MA (US)

(72) Inventors: Julian G. Blake, Gloucester, MA (US); Dale K. Stone, Lynnfield, MA (US); Lyudmila Stone, Lynnfield, MA (US); Michael Schrameyer, Beverly, MA (US)

(73) Assignee: Varian Semiconductor Equipment Associates, Inc., Gloucester, MA (US)

(21) Appl. No.: 13/871,273

(22) Filed: Apr. 26, 2013

(51) Int. Cl. H01L 21/683

(52) U.S. Cl. CPC H01L 21/6831
USPC 118/725; 361/234

(57) ABSTRACT

An electrostatic chuck includes a heater and an electrode disposed on the heater. The electrostatic chuck also includes an insulator layer and coating disposed on the insulator, where the coating is configured to support an electrostatic field generated by the electrode system to attract a substrate thereto.

### FIELD

This disclosure relates to substrate processing. More particularly, the present disclosure relates to improved electrostatic chucks for substrate processing.

### BACKGROUND

Modern substrate processing for applications such as manufacturing semiconductor devices, solar cell manufacturing, electronic component manufacturing, sensor fabrication, and micro-electromechanical device manufacturing, among others often entails an apparatus (“tool”) that employ electrostatic holders or “chucks” to hold a substrate during processing. Examples of such apparatus include chemical vapor deposition (CVD) tools, physical vapor deposition (PVD) tools, substrate etching tools such as reactive ion etching (RIE) equipment, ion implantation systems, and other apparatus. In each of these apparatus it may be desirable to heat a substrate to an elevated temperature.

In order to heat a substrate to elevated temperatures, electrostatic chuck (ESC) apparatuses have been designed with a heater which may be adjacent to or embedded in an insulating material that forms the body of an ESC. When substrates are to be processed at elevated temperatures, the heater is used to apply heat to the back (back side) of a substrate, such as a wafer, while gas is simultaneously directed to the back of the substrate in a gap or gaps provided between the front surface of the ESC and the substrate. The gas thereby becomes heated and provides a source of conductive heating to the substrate which is in contact with the heated gas. In order to efficiently heat substrates to elevated temperatures using such an ESC, it is desirable to minimize radiation heat loses which may be significant. In order to reduce power losses when the ESC is heated to elevated temperatures, heat shields and/or low emissivity coatings may be employed along the ESC edge and rear surface of the ESC that faces away from the substrate. For example, an ESC that is heated to 500° C. typically may lose on the order of 1 kW of power through the clamping surface of the ESC, may lose an additional 150 W through an outer edge, and may lose another 150 W through the rear surface of the ESC with a radiation shield in place. Although low emissivity coatings may be effective in reducing emission from different surfaces of an ESC, such low emissivity coatings are metallic and therefore are conductors of electric charge. Accordingly, such coatings cannot be deployed on the ESC front surface since an insulating layer is required on the front surface of the electrostatic clamp in order to generate a clamping electrostatic field. Thus, the large power losses due to emission through a front surface of the ESC remain a challenge. In view of the foregoing, it will be appreciated that there is a need to improve electrostatic clamps especially in equipment in which the electrostatic clamps are designed to operate at elevated temperature.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment an electrostatic chuck includes a heater and an electrode disposed on the heater. The electrostatic chuck also includes an insulator layer and low emissivity coating disposed on the insulator, where the low emissivity coating is configured to support an electrostatic field generated by the electrode system to attract a substrate thereto.

In a further embodiment, an ion implantation system includes an ion source to produce ions to implant into the substrate and a substrate holder system comprising an electrostatic chuck configured to hold the substrate during exposure to the ions. The electrostatic chuck includes a gas flow system to supply gas between the electrode and the substrate; a heater to heat the gas between the electrode and the substrate; an electrode disposed on the heater; and a low emissivity coating disposed on the heater and configured to support an electrostatic field generated by the electrode system to attract a substrate thereto.

### BRIEF DESCRIPTION OF THE DRAWINGS

FIG. 1 depicts an ion implantation system consistent with various embodiments of the disclosure;

FIG. 2 depicts an electrostatic chuck system consistent with the present embodiments;

FIG. 3 depicts a side cross-sectional view of a portion of an exemplary electrostatic chuck;

FIG. 4 depicts operation of an exemplary electrostatic chuck;

FIG. 5 depicts optical properties of an exemplary low emissivity coating;

FIG. 6 depicts another electrostatic chuck system consistent with the present embodiments;

FIG. 7 depicts a further electrostatic chuck system consistent with the present embodiments; and

FIG. 8 depicts a side cross-sectional view of a portion of another exemplary electrostatic chuck.

### DETAILED DESCRIPTION

The present embodiments will now be described more fully hereinafter with reference to the accompanying drawings, in which various embodiments are shown. The subject of this disclosure, however, may be embodied in many different forms and should not be construed as limited to the embodiments set forth herein. Rather, these embodiments are provided so that this disclosure will be thorough and complete, and will fully convey the scope of the subject of this disclosure to those skilled in the art. In the drawings, like numbers refer to like elements throughout.

Various embodiments involve apparatus and systems to process a workpiece or substrate at elevated temperatures. The term “elevated temperature” as used herein, refers to substrate temperatures generally greater than about 50° C. Various embodiments are particularly useful for processing substrates at temperatures in excess of about 200° C. The present embodiments are generally related to heated electrostatic chucks that are capable of operating at elevated temperatures. The electrostatic chucks of the present embodiments are configured to heat a substrate while simultaneously holding the substrate using electrostatic force. The terms “holding” and “hold” as used herein with respect to an ESC refer to maintaining a substrate in a desired position. An ESC apparatus may hold a substrate via an electrostatic force that is generated by the ESC, with minimal physical contact between the ESC and substrate.

Examples of apparatus that may employ heated electrostatic chucks of the present embodiments include chemical vapor deposition (CVD) tools, physical vapor deposition (PVD) tools, substrate etching tools such as reactive ion etching (RIE) equipment, ion implantation systems, and other apparatus.

In the following description and/or claims, the terms “on,” “overlying,” “disposed on” and “over” may be used in the following description and claims. “On,” “overlying,” “disposed on” and “over” may be used to indicate that two or more elements are in direct physical contact with each other. However, “on,”, “overlying,” “disposed on,” and over, may also mean that two or more elements are not in direct contact with each other. For example, “over” may mean that one element is above another element but not contact each other and may have another element or elements in between the two elements. Furthermore, the term “and/or” may mean “and”, it may mean “or”, it may mean “exclusive-or”, it may mean “one”, it may mean “some, but not all”, it may mean “neither”, and/or it may mean “both”, although the scope of claimed subject matter is not limited in this respect.

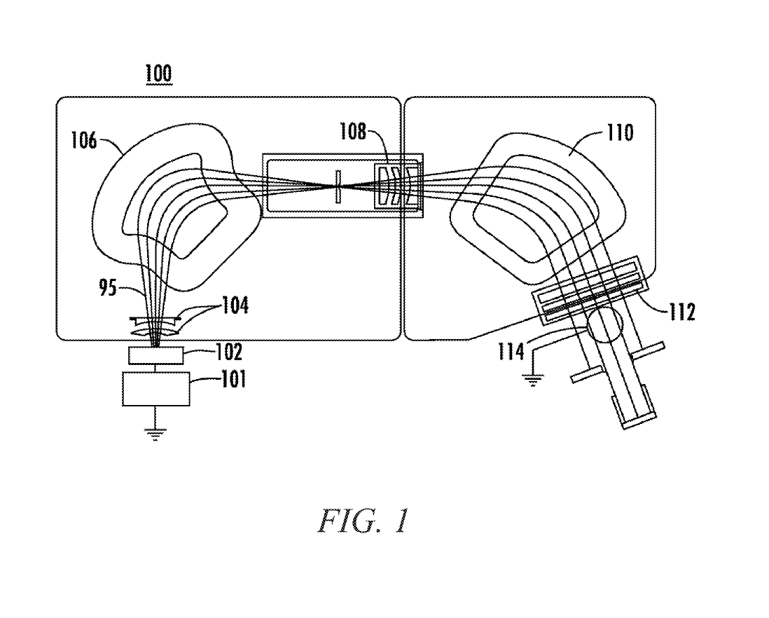

FIG. 1 presents a block diagram of an ion implantation system 100 that may employ a heated electrostatic chuck designed according to the present embodiments. As illustrated, the ion implantation system 100 includes an ion source 102. A power supply 101 supplies the required energy to ion source 102 which is configured to generate ions of a particular species. The generated ions are extracted from the source through a series of electrodes 104 (extraction electrodes) and formed into a beam 95 which is directed and manipulated by various beam components 95,106,108,110,112 to a substrate. In particular, after extraction, the beam 95 passes through a mass analyzer magnet 106. The mass analyzer is configured with a particular magnetic field such that only the ions with a desired mass-to-charge ratio are able to travel through the analyzer. Ions of the desired species pass through deceleration stage 108 to corrector magnet 110. Corrector magnet 110 is energized to deflect ion beamlets in accordance with the strength and direction of the applied magnetic field to provide a ribbon beam targeted toward a work piece or substrate positioned on substrate holder system (e.g. platen) 114. In some cases, a second deceleration stage 112 may be disposed between corrector magnet 110 and substrate holder system 114. The ions lose energy when they collide with electrons and nuclei in the substrate and come to rest at a desired depth within the substrate based on the acceleration energy.

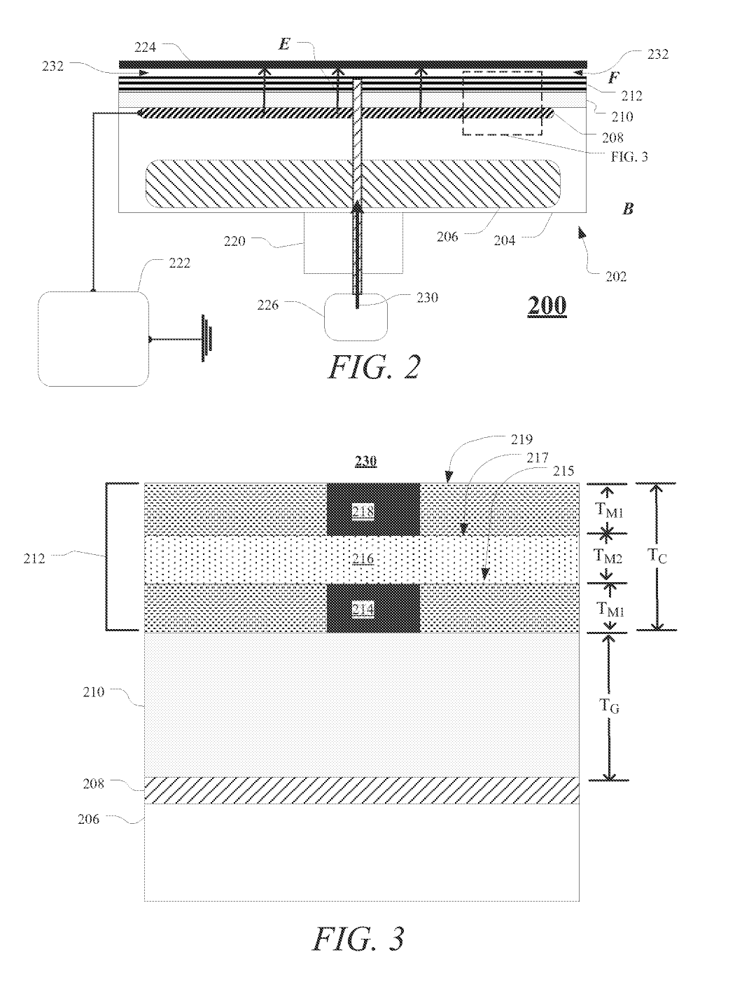

In various embodiments a substrate holder system 114 may include a heated electrostatic chuck as described with respect to the figures to follow. FIG. 2 depicts an examplary electrostatic chuck system 200 having an electrostatic chuck 202 and a stage 220 to support the electrostatic chuck. The electrostatic chuck 202 includes an insulating body 204, heater 206, and an electrode or electrode system 208, all of which may be constructed from conventional components and arranged according to conventional heated electrostatic chucks. For simplicity, by convention, the side of the electrostatic chuck 202 attached to stage 220 may be deemed the back (B) and the side of the electrostatic chuck 202 facing the substrate 224 may be deemed the front (F). Generally, the heater 206 may be disposed within the insulating body 204 and/or may be disposed toward the back B. The electrode system 208 is also generally disposed in the interior of the electrostatic chuck 202 such that insulating materials lie between the electrode system 208 and exterior 234, as shown in FIG. 3.

In various embodiments, the heater 206 may comprise various known heater designs for heating the electrostatic chuck 202. Moreover, although shown as a single component, in various embodiments, the electrode system 208 may include one or multiple components. In particular, the electrode system 208 can be a foil, a plate, multiple separate plates, a perforated foil or a perforated plate, a mesh, a screen printed layer or can have some other configuration that is suitable for incorporation into electrostatic chucks.

As also shown in FIG. 2, the electrostatic chuck 202 includes an insulator layer 210 and coating 212. The insulator layer 210 may be a conventional glass material, for example. The electrostatic chuck system 200 further includes a voltage supply 222 that is configured to apply a voltage to the electrode system 208 in order to generate a clamping force to hold a substrate 224. The heater 206 is configured to heat the electrostatic chuck 202, and thereby heat the substrate 224. A gas supply 226 is operative to supply a gas 230, such as He or other gas (not separately shown) into the backside gas region 232 between the electrostatic chuck 202 and substrate 224 in order to provide a thermally conductive medium that transfers heat generated by the electrostatic chuck 202 to the substrate 224. Accordingly, during operation of the heater 206 the electrostatic chuck 202 heats the substrate 224 primarily by heat conduction.

In order to minimize power loss during heating of the substrate 224 the coating 212 is disposed on the insulator layer 210 between the electrode system 208 and exterior 234 of the electrostatic chuck 202 (shown in FIG. 3). The coating 212 acts as a low emissivity coating to reduce energy loss due to blackbody radiation emanating from the electrostatic chuck 202. This reduction in energy loss thereby reduces the power required to heat the substrate 224 to a given temperature because a larger fraction of power generated by the heater 206 is consumed in conductively heating the substrate 224. Notably, at temperatures in excess of about 200° C., black body radiation may comprise a significant source of energy generated by the hot electrostatic chuck 202. Moreover, in a temperature range of 200° C. to about 1000° C. or higher, a majority of energy radiated by an ideal blackbody emitter takes place in the infrared wavelength range, with a peak intensity ranging from a wavelength of about 5 μm to about 2 μm. Various substrates such as silicon substrates are highly transparent to radiation in this range and therefore may absorb little, if any, energy generated by the electrostatic chuck in the form of blackbody radiation. Accordingly, such radiated energy may be wasted, thereby reducing the efficiency of substrate heating by electrostatic chuck 202, since only conductive heating generated from the electrostatic chuck 202 is effective in heating the substrate 224. As detailed below the coating 212 reduces the radiation loss by reflecting radiation generated by portions of the electrostatic chuck below the low emissivity coating.

FIG. 3 depicts a side cross-sectional view of a portion of the electrostatic chuck 202. As shown in FIG. 3, the coating 212 includes a plurality of layers which form a dielectric interference stack. Although the embodiment of FIG. 3 depicts a three-layer interference stack, in various embodiments, the coating 212 may have any desired number of layers. For example, the coating 212 may include layers 214 and 218 with a layer 216 disposed therebetween. The refractive indices of the different layers 214, 216, 218 may be configured such that reflectivity is enhanced for the coating 212 for electromagnetic radiation (also referred to herein merely as “radiation”) of a desired wavelength range. In various embodiments the layers 214, 218 constitute the same material and have the same dielectric constant or refractive index at an electromagnetic radiation wavelength range of interest, while the layer 216 constitutes a material different from that of layers 214, 218, and has a different refractive index.

In one particular example, the layers 214, 218 constitute tantalum pentoxide (Ta₂O₅), while the layer 216 constitutes SiO₂. As is well known, these materials have substantially different refractive indices, including within the infrared radiation wavelength range of between about 1 and 10 μm. Such a stack of layers 214-218 is well suited to perform as an interference stack in which reflection of electromagnetic radiation at one or more of the interfaces 215, 217, and 219 is enhanced due to the abrupt change in refractive index between adjacent layers. In some embodiments, the thickness of the first material that forms layers 214 and 218 may be the same in each layer as indicated by the thickness T_{M1} in FIG. 3. The thickness T_{M2} of the second material that forms layer 216 may or may not differ from thickness T_{M1}. The thicknesses of different layers of the low emissivity coating and the refractive index are designed to generate maximum constructive interference for electromagnetic waves reflected from adjacent interfaces. This may be accomplished by designing layer thickness and refractive index for a given layer of the coating 212 to generate a phase shift in electromagnetic radiation of a given wavelength λ₀ reflected from adjacent surfaces that is equivalent to λ₀/4. In this manner, the coating 212 may be designed to reduce the emission of electromagnetic radiation from the electrostatic chuck 202 when at an elevated temperature by increasing the amount of radiation generated by the electrostatic chuck 202 that is reflected by the coating 212.

An advantage provided by the electrostatic chuck design shown in FIGS. 2 and 3 is that since the stack of layers 214-218 of the coating 212 is composed of dielectric materials such as, for example, Ta₂O₅ and SiO₂, the coating 212 does not shield an electrostatic field E that is generated by the electrode system 208 when voltage supply 222 applies voltage to the electrode system 208. Accordingly, unlike the situation for a metallic coating, the coating 212 allows the electrode system 208 to exert a clamping force on a substrate 224 disposed proximate the insulator layer 210 as shown in FIG. 2, while reducing emission of electromagnetic radiation when the electrostatic chuck is heated.

Continuing with the example of FIG. 3, in order to ensure that the electrostatic chuck 202 generates sufficient clamping force to attract the substrate 224, the thickness T_{C} of the coating 212 may be designed to be a small fraction of the thickness T_{G} of the insulator layer. In some embodiments, for example, the ratio of T_{C}/T_{G} may be about 0.005-0.05 or about 0.5-5%. For example, the value of T_{G} of the insulator layer 210 may be in the range of about 100 μm and the thickness T_{C} of the coating 212 may be about 0.5 μm to about 5 μm. In this manner, the electrostatic field strength of a field generated by the electrode system 208 is not substantially affected by the addition of the coating 212 between the insulator layer 210 and substrate 224, since the thickness T_{C} of the coating 212 adds a relatively small increase to the total thickness (T_{C}+T_{G}) of the insulating materials (insulator layer 210 and coating 212) and that are disposed above the electrode system 208.

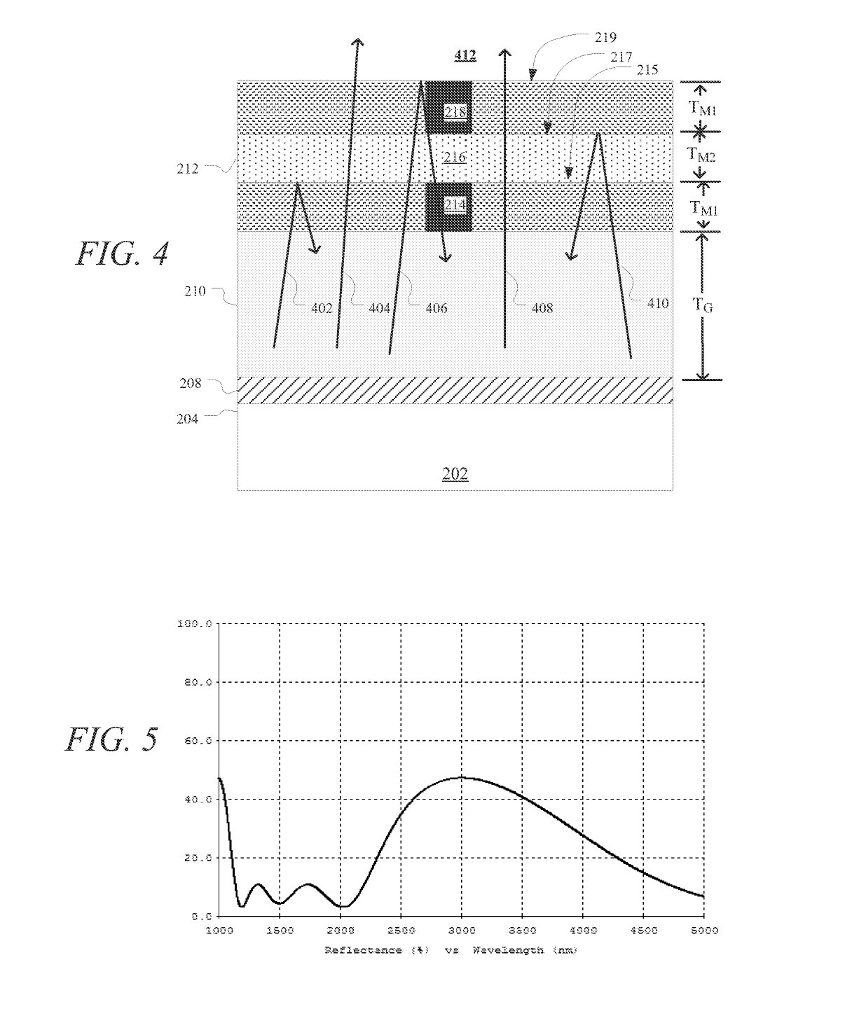

FIG. 4 depicts one scenario of operation of an electrostatic chuck 202 consistent with the present embodiments. For clarity only a portion of the electrostatic chuck 202 is illustrated. In the scenario shown in FIG. 4 the electrostatic chuck 202 is heated to elevated temperature. In one example, the electrostatic chuck 202 temperature may be heated to 500° C., which temperature induces the generation of electromagnetic radiation over a range of wavelengths whose peak wavelength range is about 3-4 μm. The electromagnetic radiation at various wavelengths is depicted as a series of rays 402, 404, 406, 408, 410 that are generated from within the electrostatic chuck 202 and are directed generally outwardly from interior portions of the electrostatic chuck 202 toward the exterior region 412 of the electrostatic chuck 202. It is to be noted that radiation may be generated by the electrostatic chuck that proceeds in other directions. As illustrated, the rays 404, 408 are transmitted through the coating 212 and emerge in the exterior region 412. The rays 402, 406, and 410, on the other hand, are reflected backwardly into the interior of the electrostatic chuck 202. More specifically, the ray 402 is reflected at interface 215, the ray 406 at interface 219, and the ray 410 at interface 417. Accordingly, a substantial fraction of the electromagnetic radiation generated by the electrostatic chuck 202 is not emitted from the surface represented by the interface 219.

In contrast, in conventional electrostatic chucks that operate at elevated temperature, the lack of the coating 212 permits electromagnetic radiation generated within the electrostatic chuck to be emitted without reflection from an outer surface, thereby resulting in a high emissivity and an unwanted energy loss from the electrostatic chuck.

FIG. 5 illustrates optical properties of an exemplary low emissivity coating (e.g. 212), which is composed of a multilayer dielectric interference stack as described above. In this example shown, the low emissivity coating is disposed on a glass substrate and reflectance is measured as a function of wavelength of radiation. As shown in the FIG. 5, the reflectance increases rapidly at wavelengths greater than about 2 μm (2000 nm) and remains above 20% for wavelengths up to nearly 4. 5 μm. This range of wavelength constitutes a peak range of blackbody emission for temperatures in the range of about 300° C. to 700° C. Accordingly, the exemplary low emissivity coating of FIG. 5 is particularly useful to reduce radiation loss from a high temperature electrostatic chuck operating in such a temperature range. When used to coat an electrostatic chuck, the dielectric low emissivity coating of FIG. 5 may reduce emissivity from about 0.7 without such a coating to about 0.3-0.4, resulting in a reduction of radiated power by about a factor of two from the front surface of an electrostatic chuck, that is, the surface facing a substrate. In this manner, a substantially larger fraction of power generated by a heater of an electrostatic chuck is used to conductively heat a substrate when the low emissivity coating is present on the electrostatic chuck.

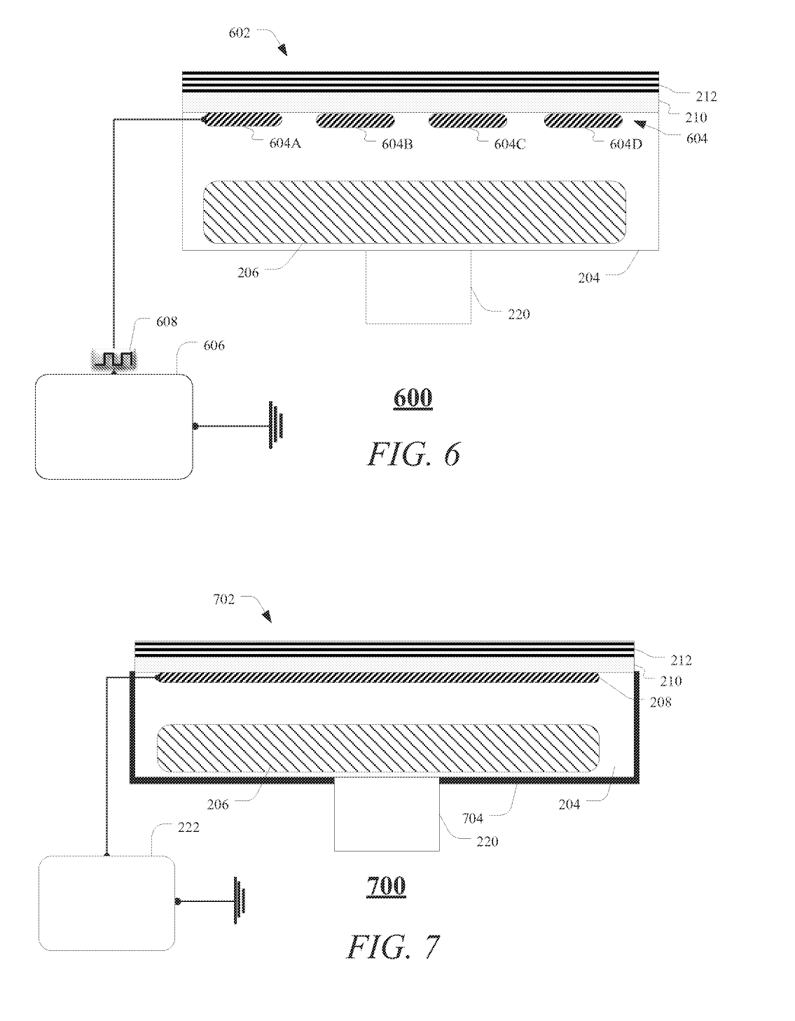

FIG. 6 depicts a further embodiment of an electrostatic chuck system 600 in which the electrostatic chuck 602 includes an electrode system 604 that includes multiple separate electrodes 604A, 604B, 604C, 604D. In some cases the electrodes may be arranged in electrode pairs as in conventional electrostatic chucks in which a clamping voltage is applied between two electrodes of an electrostatic pair. In examples in which multiple electrode pairs are included, a clamping voltage may be applied in periodic fashion between two electrodes in an electrode pair such that at any given time at least one electrode pair exerts a clamping voltage therebetween. As further shown in FIG. 6, a voltage supply 606 is configured to supply voltage as a waveform 608, which in different embodiments may be designed according to the number of electrode pairs in an electrodes system, such as electrode system 604. For a three-electrode-pair system, for example, a square wave three phase waveform may be generated to ensure that at least four electrodes are active at a given time.

FIG. 7 depicts a further embodiment of an electrostatic chuck system 700 in which the electrostatic chuck 702 includes an additional low emissivity coating 704 that is disposed on the sides and back of the electrostatic chuck. In this embodiment, the low emissivity coating 704 comprises a metallic material, which may reduce the emissivity of the side and back surfaces of electrostatic chuck 702 to a low value such as 0.3 or lower for operating temperatures in the range of about 250° C. to 1000° C. This further reduces the overall power radiated from the electrostatic chuck as electromagnetic radiation. Because the sides and back of electrostatic chuck 702 do not have to support a clamping field, the material used for low emissivity coating 704 may be any convenient metallic material.

In further embodiments, an electrostatic chuck system may be configured to support interchangeable electrostatic chucks in which different electrostatic chucks are designed for operation over different temperature ranges. Thus, a first electrostatic chuck, such as electrostatic chuck 202, may be coated with the coating 212, in which the layers 214-218 are designed for optimal reduction of emissivity at 500° C. As noted, this is accomplished by choice of refractive index and layer thickness for the layers 214, 216, 218, which may be tailored to produce peak reflectivity in a wavelength range corresponding to the peak in blackbody radiation at 500° C. The electrostatic chuck 202 may be installed when substrate processing is to take place in a given temperature range, such as 450° C. to 550° C. A second electrostatic chuck may be designed with a different low emissivity coating for operation in a different temperature range. In one example, the refractive index and thickness of layers 214, 216, 218 may be tuned to generate a reflectivity of greater than 20% for electromagnetic radiation wavelengths between about 2.5 μm and 5.0 μm, which may be suitable for reducing emissivity when substrate processing is to take place in a given temperature range, such as 450° C. to 550° C.

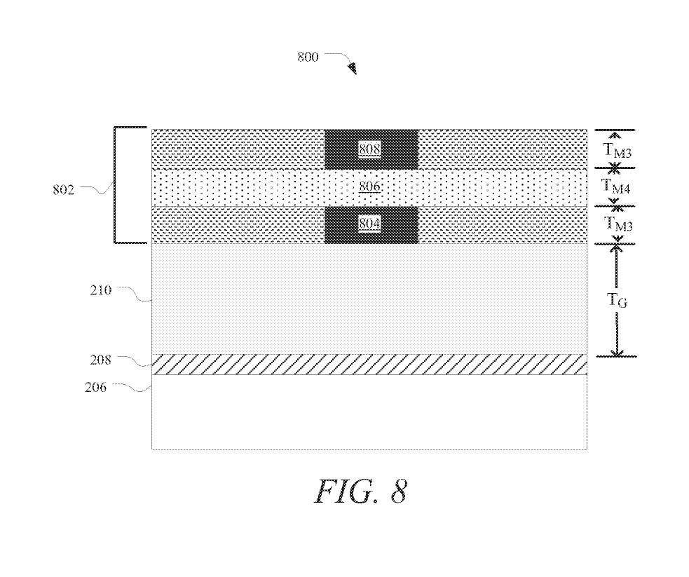

Turning to FIG. 8 there is shown a portion of an electrostatic chuck 800 having low emissivity. The electrostatic chuck 800 includes the coating 802, in which the layers 804, 806, 808 are designed for optimal reduction of emissivity at 700° C. This is accomplished by choice of refractive index and layer thickness for the layers 804, 806, 808 such that a peak reflectivity takes place in a wavelength range corresponding to the peak in blackbody radiation at 700° C. The electrostatic chuck 800 may be installed when substrate processing is to take place in a given temperature range, such as 650° C. to 750° C. In one example, the refractive index and thickness of layers 804, 806, 808 may be tuned to generate a reflectivity of greater than 20% for electromagnetic radiation wavelengths between about 1.5 μm and 5.0 μm, which may be suitable for reducing emissivity when substrate processing is to take place in a given temperature range, such as 650° C. to 750° C.

Referring again to FIG. 2, in additional embodiments, the coating 212 may constitute a broadband high reflection coating that has a high degree of reflectivity over a desired wavelength range. Such broadband dielectric coatings may involve two or more known components that are used to construct a modified quarter-wave stack in which the layers are not all the same optical thickness. Instead, they are graded between the quarter-wave thickness for two wavelengths at either end of the intended broadband performance region. The optical thicknesses of the individual layers are usually chosen to follow a simple arithmetic or geometric progression. By using designs of this type, a coating 212 constructed from a multilayer broadband stack may exhibit a reflectance in excess of 99 percent over several hundred nanometers. For example, a coating 212 may be constructed from a multilayer broadband stack designed to have a reflectivity greater than 90% between 1 and 6 μm. This makes the coating 212 useful for reducing emission from a heated ESC over a large wavelength range, thus facilitating operation of a single ESC over a large temperature range.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes.

What is claimed is:

1. An electrostatic chuck, comprising:
a heater;
an electrode disposed on the heater;
an insulator layer disposed on the electrode; and
a coating, disposed on the insulator, configured to support an electrostatic field generated by the electrode to attract a substrate thereto.

2. The electrostatic chuck of claim 1, wherein the coating comprises a plurality of dielectric layers configured to reduce emissivity from the electrostatic chuck.

3. The electrostatic chuck of claim 1, wherein the insulator is a glass layer.

4. The electrostatic chuck of claim 1, wherein the coating comprises a first thickness t_{C}, the insulator comprises a second thickness t_{G}, wherein t_{C}/t_{G} is about 0.005 to 0.05.

5. The electrostatic chuck of claim 2, wherein the plurality of dielectric layers are configured to generate an average reflectivity of greater than 20% for electromagnetic radiation wavelengths between about 2.5 μm and 5.0 μm.

6. The electrostatic chuck of claim 2, wherein the plurality of dielectric layers are configured to generate an average reflectivity of greater than 20% for electromagnetic radiation wavelengths between about 1.5 μm and 5.0 μm.

7. The electrostatic chuck of claim 2, wherein the plurality of dielectric layers comprise two or more dielectric layers in which refractive index varies between adjacent dielectric layers.

8. The electrostatic chuck of claim 2, wherein the plurality of dielectric layers comprising a total thickness of about 0.5 μm to about 5 μm.

9. The electrostatic chuck of claim 1, comprising a gas source configured to supply gas between an outer surface of the coating and a substrate.

10. The electrostatic chuck of claim 1, wherein the electrostatic chuck is heated to 500° C. and the power loss from the heater is at least 25% greater when the coating is removed from the electrostatic chuck than when the coating is present.

11. The electrostatic chuck of claim 1, further comprising one or more additional electrodes disposed on the heater.

12. An ion implantation system, comprising:
an ion source to produce ions to implant into the substrate; and
a substrate holder system comprising an electrostatic chuck configured to hold the substrate during exposure to the ions, the electrostatic chuck comprising:
a gas flow system to supply gas between the electrode and the substrate;
a heater to heat the gas between the electrode and the substrate;
an electrode disposed on the heater;
and
a coating disposed on the heater and configured to support an electrostatic field generated by the electrode system to attract a substrate thereto.

13. The ion implantation system of claim 12, the coating comprising a plurality of dielectric layers configured to reduce emissivity from the electrostatic chuck.

14. The ion implantation system of claim 12, further comprising a glass layer disposed between the electrode system and the coating, wherein the coating comprises a thickness t_{c}, the glass layer comprises a second thickness t_{G}, where t_{C}/t_{G} is about 0.005 to 0.05.

15. The ion implantation system of claim 13, wherein the plurality of dielectric layers comprise two or more dielectric layers in which refractive index varies between adjacent dielectric layers.

16. The ion implantation system of claim 13, the substrate holder system configured to interchangeably house at a first instance a first electrostatic chuck having a first coating configured to maximize electromagnetic radiation reflectivity for black body radiation at a first temperature, and at a second instance a second electrostatic chuck having a second coating configured to maximize electromagnetic radiation reflectivity for black body radiation at a second temperature different than the first temperature.

17. The ion implantation system of claim 16, wherein the first coating is configured to generate an average reflectivity of greater than 20% for electromagnetic radiation wavelengths between about 2.5 μm and 5.0 μm, and wherein the second coating is configured to generate an average reflectivity of greater than 20% for electromagnetic radiation wavelengths between about 1.5 μm and 5.0 μm.

18. The ion implantation system of claim 12, wherein the coating comprises a broadband high reflection coating having a reflectivity greater than 90% between 1 and 6 μm.
